(19) United States
(12) Patent Application Publication
(10) Pub. No.: US 2026/0150289 A1
(43) Pub. Date: May 28, 2026

(54) THREE-DIMENSIONAL MEMORY DEVICES AND FABRICATING METHODS THEREOF

(71) Applicant: Yangtze Memory Technologies Co., Ltd., Wuhan (CN)

(72) Inventors: Kun Zhang, Wuhan (CN); Wenxi Zhou, Wuhan (CN); Wei Huang, Wuhan (CN); Liang Chen, Wuhan (CN); Yanwei Shi, Wuhan (CN); Wenshan Xu, Wuhan (CN); Zhiliang Xia, Wuhan (CN); Zongliang Huo, Wuhan (CN)

(21) Appl. No.: 19/011,396

(22) Filed: Jan. 6, 2025

(30) Foreign Application Priority Data
Nov. 26, 2024 (CN) 202411707501.3

(51) Int. Cl. H10B 43/27; G11C 16/04; H10B 41/10; H10B 41/27; H10B 41/35; H10B 43/10; H10B 43/35

(52) U.S. Cl. CPC H10B 43/27; G11C 16/0483; H10B 41/10; H10B 41/27; H10B 41/35; H10B 43/10; H10B 43/35

(57) ABSTRACT

Memory devices and fabricating methods thereof are disclosed. A disclosed memory device comprises a first semiconductor structure comprising an array region and a contact region. The array region comprises an array region stack comprising conductive layers and first dielectric layers that are interleaved in a vertical direction, and an array of channel structures each vertically extending through the array region stack. The contact region comprises first transistors, a dielectric stack on the transistors and comprising the first dielectric layers and second dielectric layers that are interleaved in the vertical direction, first contact structures extending in the dielectric stack and each being connected with a corresponding one of the conductive layers in the array region stack, and second contact structures extending through the dielectric stack and in contact with the first transistors.

### CROSS-REFERENCE TO RELATED APPLICATIONS

This application claims the benefit of priority to Chinese Application No. 202411707501.3, filed on Nov. 26, 2024, which is hereby incorporated by reference in its entirety.

### TECHNICAL FIELD

The present disclosure generally relates to the field of semiconductor technology, and more particularly, to three-dimensional (3D) memory devices, and fabricating methods for forming three-dimensional (3D) memory devices.

### BACKGROUND

Planar memory cells are scaled to smaller sizes by improving process technology, circuit design, programming algorithm, and fabrication process. However, as feature sizes of the memory cells approach a lower limit, planar process and fabrication techniques become challenging and costly. As such, memory density for planar memory cells approaches an upper limit. A three-dimensional (3D) memory architecture can address the density limitation in planar memory cells. As semiconductor technology advances, 3D memory devices, such as 3D NAND memory devices, keep reducing costs and increasing capacity.

### SUMMARY

Three-dimensional (3D) memory devices and fabricating methods thereof are disclosed herein.

One aspect of the present disclosure provides a memory device, comprising: a first semiconductor structure comprising: an array region comprising: an array region stack comprising conductive layers and first dielectric layers that are interleaved in a vertical direction, and an array of channel structures each vertically extending through the array region stack; and a contact region comprising: first transistors, a dielectric stack on the transistors and comprising the first dielectric layers and second dielectric layers that are interleaved in the vertical direction, first contact structures extending in the dielectric stack and each being connected with a corresponding one of the conductive layers in the array region stack, and second contact structures extending through the dielectric stack and in contact with the first transistors.

In some implementations, the contact region comprising further comprises: a bridge stack on a lateral side of the dielectric stack and comprising the conductive layers and the first dielectric layers that are interleaved in the vertical direction; wherein each of the first contact structure is connected with the corresponding one of the conductive layers through the bridge stack.

In some implementations, the memory device further comprises a first semiconductor layer in the array region and the contact region, wherein: the array region stack, the dielectric stack, and the bridge stack are located on the first semiconductor layer; each channel structure extending through the first semiconductor layer in the array region; and portions of the first semiconductor layer in the contact region comprise gate structures of the first transistors.

In some implementations, the memory device further comprises a second semiconductor layer in the contact region, on a side of the first semiconductor layer opposite to the dielectric stack, and comprising sources and drains of the first transistors.

In some implementations, the memory device further comprises isolation structures extending through the first semiconductor layer in the contact region, and laterally surrounding the gate structure of each first transistor.

In some implementations, the second contact structures comprise: gate contacts extending through the dielectric stack and in contact with the first semiconductor layer; and source/drain contacts extending through the dielectric stack and the first semiconductor layer, and in contact with the second semiconductor layer.

In some implementations, the first contact structure comprises: a vertical conductive structure vertically extending in the dielectric stack; and a lateral conductive structure at a bottom of the vertical conductive structure and laterally in contact with the corresponding one of the conductive layers of the bridge stack.

In some implementations, each first contact structure further comprises: a spacer layer laterally surrounding the vertical conductive structure to separate the vertical conductive structure from the dielectric stack.

In some implementations, the memory device further comprises a first slit structure and a second slit structure extending in parallel along a first lateral direction and vertically in the array region stack and the bridge stack, wherein: the bridge stack comprises a first portion adjacent to the first slit structure and a second portion adjacent to the second slit structure; and the dielectric stack is located between the first portion and the second portion of the bridge stack along a second lateral direction perpendicular to the first lateral direction.

In some implementations, the memory device further comprises dummy channel structures vertically extending in the bridge stack located adjacent to the first slit structure and the second slit structure.

In some implementations, the memory device further comprises a second semiconductor layer in contact with the first semiconductor layer and channel structures.

In some implementations, the memory device further comprises a second semiconductor structure comprising second transistors; wherein the first semiconductor structure and the second semiconductor structure are bonded together.

In some implementations, operating voltages of the second transistors are lower than operating voltages of the first transistors; and a first thickness of gate dielectric of the first transistors is greater than a second thickness of gate dielectric of the second transistors.

Another aspect of the present disclosure provides a memory device, comprising: a first semiconductor structure comprising: an array region comprising: an array region stack on a first semiconductor layer, and an array of channel structures each vertically extending through the array region stack; and a contact region comprising: first transistors, wherein upper surfaces of gate structures of the first transistors are aligned with an upper surface of the first semiconductor layer, a dielectric stack on the first transistors, and second contact structures extending through the dielectric stack and in contact with the first transistors.

In some implementations, the first semiconductor layer and the gate structures of the first transistors have a same thickness and a same type of dopant.

In some implementations, the array region stack comprises conductive layers and first dielectric layers that are interleaved in a vertical direction; and the dielectric stack comprises the first dielectric layers and second dielectric layers that are interleaved in the vertical direction.

In some implementations, the contact region further comprises: a bridge stack comprising the conductive layers and the first dielectric layers that are interleaved in the vertical direction; and first contact structures extending in the dielectric stack and each being in contact with a corresponding one of the conductive layers.

In some implementations, the memory device further comprises a second semiconductor layer in the contact region, on a side of the gate structures of the first transistors opposite to the dielectric stack, and comprising sources and drains of the first transistors.

In some implementations, the memory device further comprises isolation structures extending though the first semiconductor layer in the contact region, and laterally surrounding the gate structure of each first transistor.

In some implementations, the second contact structures comprise: gate contacts extending through the dielectric stack and in contact with the gate structures of the first transistors; and source/drain contacts extending through the dielectric stack and the gate structures, and in contact with the second semiconductor layer.

In some implementations, the first contact structure comprises: a vertical conductive structure vertically extending in the dielectric stack; and a lateral conductive structure at a bottom of the vertical conductive structure and laterally in contact with the corresponding one of the conductive layers of the bridge stack.

In some implementations, each first contact structure further comprises: a spacer layer laterally surrounding the vertical conductive structure to separate the vertical conductive structure from the dielectric stack.

In some implementations, the memory device further comprises a first slit structure and a second slit structure extending in parallel along a first lateral direction and vertically in the array region stack and the bridge stack, wherein: the bridge stack comprises a first portion adjacent to the first slit structure and a second portion adjacent to the second slit structure; and the dielectric stack is located between the first portion and the second portion of the bridge stack along a second lateral direction perpendicular to the first lateral direction.

In some implementations, the memory device further comprises dummy channel structures vertically extending in the bridge stack located adjacent to the first slit structure and the second slit structure.

In some implementations, the memory device further comprises a second semiconductor layer in contact with the first semiconductor layer and channel structures.

In some implementations, the memory device further comprises a second semiconductor structure comprising second transistors; wherein the first semiconductor structure and the second semiconductor structure are bonded together.

In some implementations, the memory device further comprises operating voltages of the second transistors are lower than operating voltages of the first transistors; and a first thickness of gate dielectric of the first transistors is greater than a second thickness of gate dielectric of the second transistors.

Another aspect of the present disclosure provides a method of forming a memory device, comprising: forming a substrate including a first semiconductor layer on a second semiconductor layer; forming isolation structure extending through the first semiconductor layer in a contact region; forming first transistors on the substrate in the contact region; forming a dielectric stack on the first semiconductor layer; forming an array of channel structures each vertically extending through the dielectric stack in an array region; transforming the dielectric stack in the array region into an array region stack and transforming portion of the dielectric stack in the contact region into bridge stacks; forming first contact structures extending in the dielectric stack and each being in contact with a conductive layer in the bridge stacks; and forming second contact structures extending through the dielectric stack and in contact with the first transistors.

In some implementations, the method further comprises forming sources and drains of the first transistors in a second semiconductor layer in the contact region and on a side of the first semiconductor layer opposite the dielectric stack.

In some implementations, forming the second contact structures comprises: forming contact sacrificial structures vertically extending through the dielectric stack in the contact region; after forming the first contact structures, forming second contact structures to replace the contact sacrificial structures.

In some implementations, forming the second contact structures comprises: forming gate contacts extending through the dielectric stack and in contact with the first semiconductor layer; and forming source/drain contacts extending through the dielectric stack and the first semiconductor layer, and in contact with the second semiconductor layer.

In some implementations, forming each first contact structure comprises: forming a vertical conductive structure vertically extending in the dielectric stack; and forming a lateral conductive structure at a bottom of the vertical conductive structure and laterally in contact with the conductive layers of the bridge stack.

In some implementations, forming each first contact structure further comprises: forming a spacer layer laterally surrounding the vertical conductive structure to separate the vertical conductive structure from the dielectric stack.

In some implementations, the method further comprises forming a first slit structure and a second slit structure extending in parallel along a first lateral direction and vertically in the array region stack and the bridge stack; forming the bridge stack comprises forming a first portion adjacent to the first slit structure and forming a second portion adjacent to the second slit structure; wherein the dielectric stack is formed between the first portion and the second portion of the bridge stack along a second lateral direction perpendicular to the first lateral direction.

In some implementations, the method further comprises forming dummy channel structures vertically extending in the bridge stack and located adjacent to the first slit structure and the second slit structure.

In some implementations, the method further comprises forming a second semiconductor layer in contact with the first semiconductor layer and channel structures.

In some implementations, the method further comprises forming a second semiconductor structure comprising second transistors; and bonding the second semiconductor structure to a first semiconductor structure including the array of channel structures and the first transistors.

Other aspects of the present disclosure can be understood by those skilled in the art in light of the description, the claims, and the drawings of the present disclosure.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a block diagram of a system having a memory device, according to some aspects of the present disclosure.

FIG. 2A illustrates a diagram of an exemplary memory card having a memory device, according to some aspects of the present disclosure.

FIG. 2B illustrates a diagram of an exemplary solid-state drive (SSD) having a memory, according to some aspects of the present disclosure.

FIG. 3 illustrates a planar view of a portion of a 3D memory device, according to some aspects of the present disclosure.

FIG. 4 illustrates an enlarged planar view of a portion of a 3D memory device, according to some aspects of the present disclosure.

FIG. 5 illustrates a cross-sectional view of a portion of a 3D memory device, according to some aspects of the present disclosure.

FIG. 6 illustrates a flow diagram of a method for forming a 3D memory device, according to some aspects of the present disclosure.

FIGS. 7A-7H illustrate schematics of a 3D memory device at certain fabricating stages of the method shown in FIG. 6 in a cross-sectional view according to various aspects of the present disclosure.

The present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one implementation,” “an implementation,” “an example implementation,” “some implementations,” etc., indicate that the implementation described may include a particular feature, structure, or characteristic, but every implementation may not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to effect such feature, structure or characteristic in connection with other implementations whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of lateral planes between, or at, a top surface and a bottom surface of the continuous structure. A layer can extend laterally, vertically, and/or along a tapered surface. A substrate can be a layer, can include one or more layers therein, and/or can have one or more layer thereupon, thereabove, and/or therebelow. A layer can include multiple layers. For example, an interconnection layer can include one or more conductor and contact layers (in which contacts, interconnect lines, and/or vias are formed) and one or more dielectric layers.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

As used herein, the term “3D memory device” refers to a semiconductor device with vertically-oriented strings of memory cell transistors (i.e., region herein as “memory strings,” such as NAND strings) on a laterally-oriented substrate so that the memory strings extend in the vertical direction with respect to the substrate. As used herein, the term “vertical/vertically” means nominally perpendicular to a lateral surface of a substrate.

As described above, 3D NAND memory devices keep reducing costs and increasing capacity by compressing the density of memory cells in the horizontal plane. In some 3D NAND memory devices, memory cells for storing data are vertically stacked through a stack structure (e.g., a memory stack) in vertical channel structures. 3D memory devices usually include staircase structures formed on one or more sides (edges), or at the center, of the stacked storage structure for purposes, such as word line pick-up/fan-out, using word line contacts landed onto different steps/levels of a staircase structure. Dummy channel structures are usually formed through the memory stack in regions outside of the core array region in which the channel structures of 3D NAND memory devices are formed, such as staircase regions having the staircase structures, to provide mechanical support to the stack structure, in particular, during the gate replacement process that temporarily removes some layers of the stack structure through slit openings across the core array region and staircase regions of the stack structure.

The integration of the various structures, such as dummy channel structures, word line contacts, staircase structures, slit openings, etc., from both the device design perspective and the fabrication process perspective, has become more and more challenging as the memory cell density of the 3D NAND memory devices continues increasing.

Contact structures (e.g., word line pick-up structures) are introduced to achieve the word line pick-up/fan-out functions without using staircase structures and word line contacts. For example, the two structures—staircase structure and word line contact, as well as their separate processes, can be merged into a single contact structure in one process, thereby reducing the manufacturing cost and simplifying the process. Moreover, by replacing staircase structures and word line contacts with contact structures, the scope of the gate replacement process can be reduced, such that at least some of the dummy channel structures can be eliminated as well to further reduce the cost and simplify the process.

On the other hand, multi-deck stacking is a trend in the 3D NAND memory structure design, but channel current is still a problem for super high-level boards. Moreover, it is a challenge to etch contact holes with a high Depth-to-Diameter Ratio in a multi-deck stacking structure. In addition, the channel hole arrangement in the bit line direction will be a major design concern in the future.

To address one or more of the aforementioned issues, the present disclosure introduces a new integration structure, in which a lower memory deck can have contact structures while an upper memory deck can have staircase structures. Specifically, the lower memory deck can comprise a first stack comprising interleaved lower conductive layers and first lower dielectric layers, a second stack on a lateral side of the first stack, and comprising interleaved second lower dielectric layers and the first lower dielectric layers, and lower contact structures extending in the second stack and each being in contact with a corresponding one of the lower conductive layers of the first stack. The upper memory deck can comprise a staircase structure comprising interleaved upper conductive layers and upper dielectric layers on the first stack, a dielectric filling structure on the second stack, stair contacts on the staircase structure, each stair contact being in contact with a corresponding one of the upper conductive layers, and upper contact structures each extending through the dielectric filling structure and in contact with a corresponding one of the lower contact structures. The disclosed integration design can allow more channel structure arranged in the bit line direction, thereby significantly increasing the memory density.

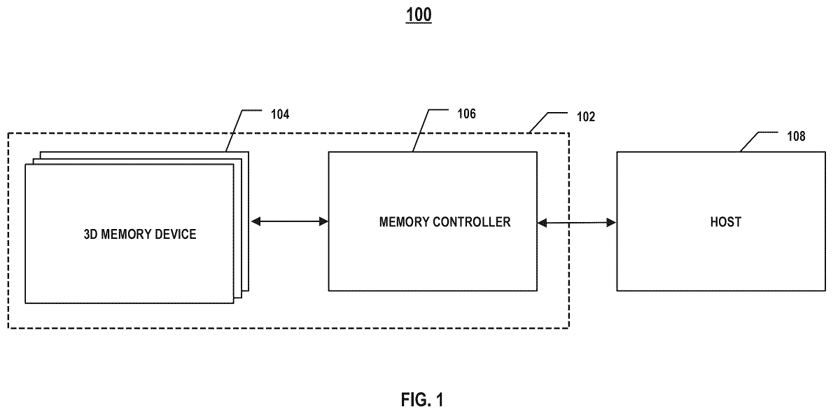

FIG. 1 illustrates a block diagram of a system 100 having a memory device, according to some aspects of the present disclosure. System 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, system 100 can include a host 108 and a memory system 102 having one or more memory devices 104 and a memory controller 106. Host 108 can be a processor of an electronic device, such as a central processing unit (CPU), or a system-on-chip (SoC), such as an application processor (AP). Host 108 can be configured to send or receive the data to or from memory devices 104.

Memory device 104 can be any memory devices disclosed herein, such as a NAND Flash memory device. Consistent with the scope of the present disclosure, memory controller 106 may control the multi-pass programming on memory device 104 such that an NGS operation is enabled on all memory cells, even those passed the respective verify operations, in a non-last programming pass of the multi-pass programming. The peripheral circuits, such as the word line drivers, may apply a low voltage, e.g., ground (GND) voltage, on the DSGs of each memory string coupled to the selected word line, and may apply a low or negative voltage on the selected word line to enable an NGS operation on all memory cells coupled to the selected word line during a non-last programming pass.

Memory controller 106 is coupled to memory device 104 and host 108 and is configured to control memory device 104, according to some implementations. Memory controller 106 can manage the data stored in memory device 104 and communicate with host 108. In some implementations, memory controller 106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 106 is designed for operating in a high duty-cycle environment SSDs or embedded multi-media-cards (eMMCs) used as data storage for mobile devices, such as smartphones, tablets, laptop computers, etc., and enterprise storage arrays. Memory controller 106 can be configured to control operations of memory device 104, such as read, erase, and program operations. Memory controller 106 can also be configured to manage various functions with respect to the data stored or to be stored in memory device 104 including, but not limited to bad-block management, garbage collection, logical-to-physical address conversion, wear leveling, etc. In some implementations, memory controller 106 is further configured to process error correction codes (ECCs) with respect to the data read from or written to memory device 104. Any other suitable functions may be performed by memory controller 106 as well, for example, programming memory device 104. Memory controller 106 can communicate with an external device (e.g., host 108) according to a particular communication protocol. For example, memory controller 106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

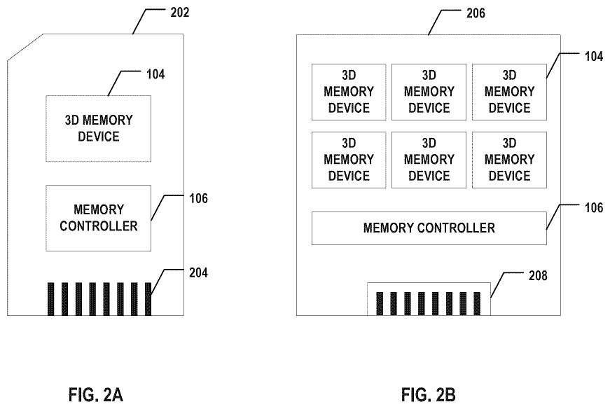

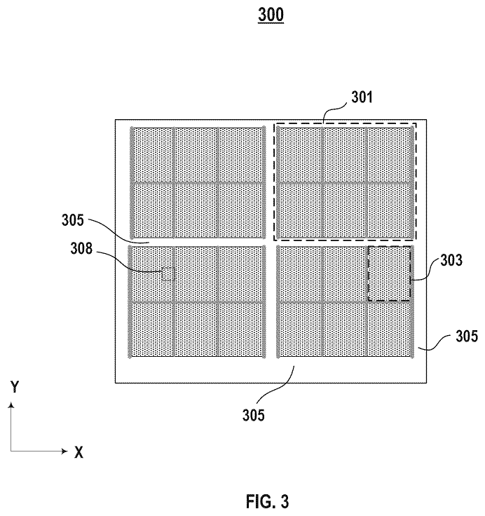

Memory controller 106 and one or more memory devices 104 can be integrated into various types of storage devices, for example, be included in the same package, such as a universal Flash storage (UFS) package or an eMMC package. That is, memory system 102 can be implemented and packaged into different types of end electronic products. In one example as shown in FIG. 2A, memory controller 106 and a single memory device 104 may be integrated into a memory card 202. Memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 202 can further include a memory card connector 204 coupling memory card 202 with a host (e.g., host 108 in FIG. 9). In another example as shown in FIG. 2B, memory controller 106 and multiple memory devices 104 may be integrated into an SSD 206. SSD 206 can further include an SSD connector 208 coupling SSD 206 with a host (e.g., host 108 in FIG. 9). In some implementations, the storage capacity and/or the operation speed of SSD 206 is greater than those of memory card 202.

FIG. 3 illustrates a planar view of a 3D memory device 300, according to some implementations of the present disclosure. 3D memory device 300 can be a memory chip (package), a memory chip or any portion of a memory chip, and can include one or more memory planes 301, each of which can include a plurality of memory blocks 303. Identical and concurrent operations can take place at each memory plane 301. Memory block 303, which can be megabytes (MB) in size, can be the smallest size to carry out erase operations. As shown in FIGS. 3, 3D memory device 300 includes four memory planes 301 and each memory plane 301 includes six memory blocks 303.

Each memory block 303 can include a plurality of memory cells, where each memory cell can be addressed through interconnections such as bit lines and word lines. The bit lines and word lines can be laid out perpendicularly (e.g., in rows and columns, respectively), forming an array of metal lines. In FIG. 3, the direction of word lines is labeled as X-direction, and the direction of bit lines is labeled as Y-direction. In this disclosure, memory block 303 is also referred to as a “memory array” or “array.” The memory array is the core area in a memory device, performing storage functions.

3D memory device 300 can include a periphery region 305, an area surrounding memory planes 301. Periphery region 305 can contain many digital, analog, and/or mixed-signal circuits to support functions of the memory array, for example, page buffers, row and column decoders, and sense amplifiers. Peripheral circuits use active and/or passive semiconductor devices, such as transistors, diodes, capacitors, resistors, etc., as would be apparent to a person of ordinary skill in the art. It is noted that, the arrangement of memory planes 301 in 3D memory device 300 and the arrangement of memory blocks 303 in each memory plane 301 illustrated in FIG. 3 are only provided as an example, which does not limit the scope of the present disclosure.

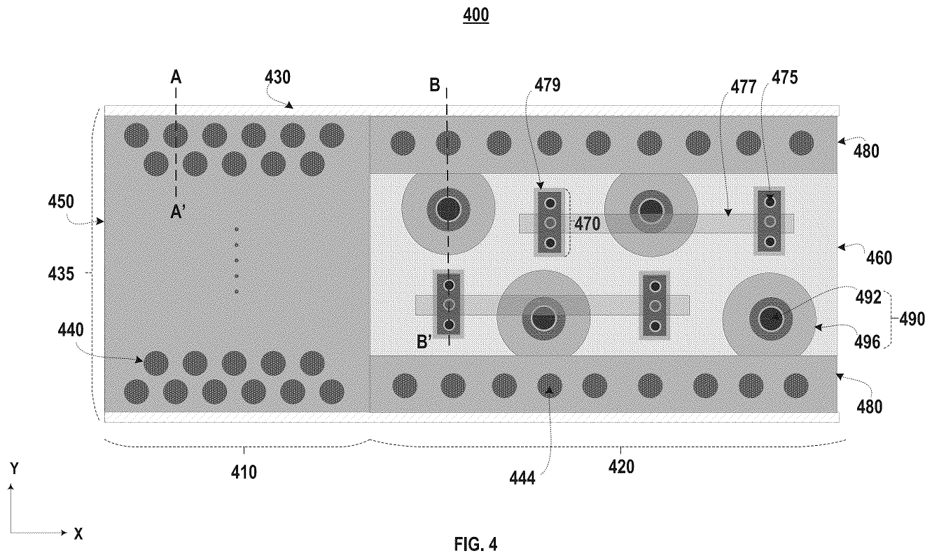

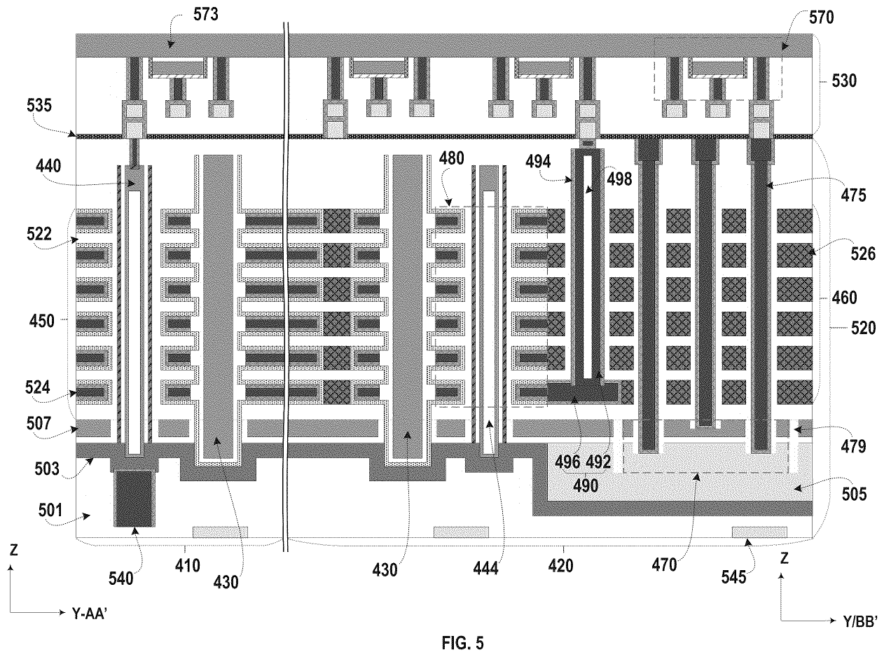

Referring to FIG. 4, a schematic diagram of a portion of a 3D memory device 400, such as region 308 of FIG. 3 is shown in an enlarged planar view, according to some implementations of the present disclosure. FIG. 5 shows schematic cross-sectional side views of portions of the 3D memory device 400 along AA′ line and BB′ line shown in FIG. 4, according to some implementations of the present disclosure. In some implementations, the 3D memory device 400 is a NAND Flash memory device in which memory cells are provided in the form of an array of NAND memory strings. It is noted that the X, Y and Z axes are included in FIGS. 4 and 5 to illustrate three orthogonal (perpendicular) directions of the 3D memory device 400. The X-direction (i.e., the first lateral direction) is the word line direction of the 3D memory device 400, the Y-direction (i.e., the second lateral direction) is the bit line direction of the 3D memory device 400, and the Z-direction is the vertical direction of the 3D memory device 400.

As shown in FIGS. 4, 3D memory device 400 can be divided into at least an array region 410 (e.g., a first region, also referred to as “core region”) in which an array of channel structures 440 are formed, as well as a contact region 420 (e.g., a second region, also referred as “word line pick-up region”) in which word line contacts 490 (e.g., word line pick-up structures) and first transistors 470 are formed. Array region 410 and contact region 420 are arranged in the X-direction (the word line direction), according to some implementations. It is understood that although one array region 410 and one contact region 420 are illustrated in FIG. 4, multiple core array regions 410 and/or multiple contact regions 420 may be included in 3D memory device 400, for example, one contact region 420 between two core array regions 410 in the X-direction, in other examples. It is also understood that FIG. 4 only illustrates portions of array region 410 that are adjacent to contact region 420. It is noted that, the array region 410 shown in FIG. 5 is the cross-sectional side view of a portion of the 3D memory device 400 along AA′ line shown in FIG. 4, and the contact region 420 shown in FIG. 5 is the cross-sectional side view of a portion of the 3D memory device 400 along BB′ line shown in FIG. 4.

As shown in FIG. 5, in some implementations, the 3D memory device 400 includes a substrate 501, and a conductive layer 503 formed on the substrate 501 in both the array region 410 and the contact region 420. In some implementations, the substrate 501 can include silicon (e.g., monocrystalline silicon, polycrystalline silicon), silicon germanium (SiGe), gallium arsenide (GaAs), germanium (Ge), silicon on insulator (SOI), or any other suitable materials. In some implementations, substrate 501 includes single crystalline silicon, which is part of the wafer on which 3D memory device 400 is fabricated, either in its native thickness or being thinned. In some implementations, substrate 501 includes, for example, poly crystalline silicon, which is a semiconductor layer replacing the part of the wafer on which 3D memory device 400 is fabricated. In some implementations, the first semiconductor layer 507 can include Si, SiGe, GaAs, Ge, or any other suitable semiconductor material.

The first semiconductor layer 507 includes two lateral surfaces extending laterally in the X-Y plane: a top surface on the front side of the first semiconductor layer 507 on which memory cell array is formed, and a bottom surface on the backside opposite to the front side of the first semiconductor layer 507. The Z-axis is perpendicular to both the X and Y axes. As used herein, whether one component (e.g., a layer or a device) is “on,” “above,” or “below” another component (e.g., a layer or a device) of 3D memory device 400 is determined relative to the first semiconductor layer 507 in the Z-direction (the vertical direction perpendicular to the X-Y plane). The same notion for describing the spatial relationship is applied throughout the present disclosure.

A stack structure can be formed on the first semiconductor layer 507. The stack structure can include an array region stack 450 in the array region 410, a dielectric stack 460 and a bridge stack 480 in the contact region 420. In some implementations, the array region stack 450 can include a plurality of conductive/dielectric layer pairs stacked vertically in the Z-direction. The conductive layers 524 and the first dielectric layers 522 can alternate in the vertical direction (the Z-direction). The conductive layers 524 can include conductive materials including, but not limited to, tungsten (W), cobalt (Co), copper (Cu), aluminum (Al), titanium nitride (TiN), polycrystalline silicon (polysilicon), doped silicon, silicides, or any combination thereof. The first dielectric layers 522 can include dielectric materials including, but not limited to, silicon oxide, silicon nitride, silicon oxynitride, or any combination thereof.

In some implementations, the 3D memory device 400 is a NAND Flash memory device, and an array of NAND memory strings are formed in the array region stack 450. Each NAND memory string comprises a channel structure 440 extending vertically through the plurality of conductive/dielectric layer pairs. The number of conductive/dielectric layer pairs in the array region stack 450 can determine the number of memory cells in the 3D memory device 400. In some implementations, the array region stack 450 can be formed by stacking two or more decks of memory stacks vertically in the Z-direction to increase the number of conductive/dielectric layer pairs, thereby increasing the memory density of the 3D memory device 400. In some implementations, each conductive layer 524 in the array region stack 450 functions as a gate line of the NAND memory strings (in the forms of channel structures 440, as well as a word line extending laterally from the gate line to the contact region 420 for word line pick-up/fan-out. In some implementations, a conductive layer 503 is formed between the substrate 501 and the first semiconductor layer 507, and in contact with the source ends of the channel structures 440 and functions as a common source line of the array of NAND memory strings. A source contact 540 can be formed in the substrate 501 and in contact with the conductive layer 503.

As shown, multiple gate line slit (GLS) structure 430 (also referred to as “slit structure”) can extend laterally in parallel along the word line direction (i.e., X-direction) and vertically through the plurality of conductive/dielectric layer pairs. The GLS structures 430 can divide the memory array into multiple memory fingers 435, such that the conductive layers between adjacent memory fingers 435 can be separated. In some implementations, GLS structure 430 is an insulating structure that does not include any interconnects therein (i.e., not functioning as the source contact) and thus, does not introduce parasitic capacitance and leakage current with the conductive layers. In some other implementations, GLS structure 430 is a source contact further including a conductive portion (e.g., including W, polysilicon, and/or TiN) circumscribed by a slit spacer portion. As described below in detail, during the gate replacement process, the slits in which the GLS structures 430 are formed can serve as the passageway and starting point for forming the conductive layers. As a result, the GLS structures 430 are surrounded by conductive layers in either array region 410 or contact region 420.

In some implementations, each memory finger 435 can include an odd number (e.g., 9, 19, 29, etc.) of rows of channel structures 440 arranged in a staggered manner between two adjacent GLS structures 430. It is understood that although one memory finger 435 is illustrated in FIG. 4, multiple memory fingers 435 may be included in 3D memory device 400, for example. In some implementations, a first portion of the GLS structure 430 in the array region 410 has a first width in the bit line direction (i.e., Y-direction), and a second portion of the GLS structure 430 in the contact region 420 has a second width in the bit line direction (i.e., Y-direction) different from the first width. For example, the first width of the first portion of the GLS structure 430 is less than the second width of the second portion of the GLS structure 430. In some other implementations as shown in FIG. 4, the GLS structure 430 has a constant width in the array region 410 and in the contact region 420.

As shown in FIGS. 4 and 5, the contact region 420 can include a plurality of first transistors 470 located on the substrate 501. In some implementations, a second semiconductor layer 505 can be formed in the contact region 420 between the first semiconductor layer 507 and the conductive layer 503, and can include any suitable semiconductor material, such as silicon (e.g., single crystalline silicon), silicon germanium (SiGe), gallium arsenide (GaAs), germanium (Ge), etc. Channel regions, source regions, and drain regions of the first transistors 470 can be formed in the second semiconductor layer 505. Portions of the first semiconductor layer 507 in the contact region 420 can function as the gate structures of the first transistors 470. An isolation structure 479 can extend through the first semiconductor layer 507 into the second semiconductor layer 505, and can laterally surround the gate structure and/or the source/drain of each first transistor 470.

The dielectric stack 460 can be located on the first semiconductor layer 507 in the contact region 420, and can comprise interleaved second dielectric layers 526 and the first dielectric layers 522. The second dielectric layers 526 and the first dielectric layers 522 can alternate in the vertical direction (the Z-direction). The second dielectric layers 526 can include dielectric materials including, but not limited to, silicon oxide, silicon nitride, silicon oxynitride, or any combination thereof. The material of the second dielectric layers 526 is different from the material of the first dielectric layers 522. In some implementations as shown in FIGS. 4 and 5, transistor contact structures 475 can extend vertically through the dielectric stack 460 and in contact with the first transistors 470. In some implementations, transistor contact structures 475 can include gate contacts in contact with the gate structures (i.e., first semiconductor layer 507) of the first transistors 470, and source/drain contacts penetrating through the first semiconductor layer 507 and in contact with source/drain regions (i.e., the second semiconductor layer 505) of the first transistors 470. In some implementations, the gate electrodes of the first transistors 470 can be connected with each other by a lateral conductive interconnect structure 477, as shown in FIG. 4. The transistor contact structures 475 and/or the lateral conductive interconnect structures 477 can include conductive materials including, but not limited to, W, Co, Cu, Al, TiN, polysilicon, doped silicon, silicides, or any combination thereof.

In some implementations as shown in FIG. 4, the dielectric stack 460 can be located between two portions of the bridge stack 480 in the bit line direction (i.e., the Y-direction). Each portion of the bridge stack 480 is located adjacent to a GLS structure 430, and comprises the conductive layers 524 and the first dielectric layers 522 alternatively stacked in the vertical direction (the Z-direction). In some implementations, each conductive layer 524 in the bridge stack 480 functions as a word line extending laterally extending from the gate line in the array region 410 to the contact region 420 for word line pick-up through word line contacts 490. The word lines (i.e., the conductive layers 524) at different depths/levels each extends laterally in array region stack 450 and bridge stack 480, but are discontinuous (e.g., being replaced by the second dielectric layers 526) at the dielectric stack 460, according to some implementations.

In some implementations, the word line contacts 490 extend vertically in the dielectric stack 460 in the contact region 420 at different depths in the Z-direction. In some implementations, each word line contact 490 includes a vertical conductive structure 492, and a lateral conductive structure 496 below and in contact with the vertical conductive structure 492. The vertical conductive structure 492 and the lateral conductive structure 496 can include conductive materials including, but not limited to, W, Co, Cu, Al, TiN, polysilicon, doped silicon, silicides, or any combination thereof. Optionally, each word line contact 490 further includes a spacer layer 494 circumscribing the vertical conductive structure 492. The spacer layer 494 can include dielectric materials including, but not limited to, silicon oxide, silicon nitride, silicon oxynitride, or any combination thereof. Optionally, each word line contact 490 further includes a filling layer 498 surrounded by the vertical conductive structure 492 and the lateral conductive structure 496. The filling layer 498 can include dielectric materials, including, but not limited to, silicon oxide, silicon nitride, silicon oxynitride, or any combination thereof. In some implementations, the vertical conductive structure 492 and the lateral conductive structure 496 include TiN/W, and the spacer layer 494 and the filling layer 498 include silicon oxide.

It is noted that, the top surfaces of different word line contacts 490 can be flush with one another, while the bottom surfaces of different word line contacts 490 can extend to different levels, for example, different second dielectric layers 526 of the dielectric stack 460. In some implementations, the lateral conductive structure 496 can be laterally in contact with a corresponding one of the conductive layers 524 of the bridge stack 480. to achieve word line pick-up/fan-out. As shown in FIG. 4, in some implementations, the word line contacts 490 in each memory finger 435 can be arranged as two rows each aligned along the word line direction (i.e., X-direction) between the GLS structures 430. In some implementations, the two rows of the word line contacts 490 are arranged in a staggered manner in the bit line direction (i.e., Y-direction). A first row of the word line contacts 490 are located adjacent to a first portion of the bridge stack 480, and a second row of the word line contacts 490 are located adjacent to a second portion of the bridge stack 480. In some implementations, each word line contact 490 in the first row is in contact with a corresponding odd conductive layer 524, and each word line contact 490 in the second row is in contact with a corresponding even conductive layer 524.

As shown in FIGS. 4 and 5, dummy channel structures 444 can extend through the bridge stack 480 to provide mechanical support and/or load balancing, according to some implementations. In some implementations, dummy channel structure 444 has the same structure as channel structure 440, because they are formed in the same fabrication process. Dummy channel structure 444, however, cannot perform the same memory functions as channel structure 440, at least because dummy channel structures 444 are not in contact with any local contact structures (e.g., channel contacts) in the local contact layer to pick-up/fan-out dummy channel structures 444, according to some implementations. It is understood that in some examples, dummy channel structures 444 and channel structure 440 may have different structures and may be formed in different fabrication processes. For example, dummy channel structures 444 may be filled with dielectric material(s) without semiconductor materials. Nevertheless, both dummy channel structures 444 and channel structures 440 can perform the mechanical supporting functions, in particular, during the gate replacement process, as described below in detail with respect to the fabrication processes.

As shown in FIG. 5, in some implementations, the 3D memory device 400 can be a bonded structure and can include a first semiconductor structure 520 comprising the channel structures 440 and the first transistors 470, and a second semiconductor structure 530 comprising a plurality of second transistors 570. As shown in FIG. 5, the second transistors 570 can be formed on or in a semiconductor layer 573. Trench isolations (e.g., shallow trench isolations (STIs), not shown) and doped regions (e.g., wells, sources, and drains of transistors) can be formed on or in the semiconductor layer 573. In some implementations, the operating voltages of the second transistors 570 are lower than the operating voltages of the first transistors 470. In some implementations, a first thickness of gate dielectric of the first transistors 470 is greater than a second thickness of gate dielectric of the second transistors 570. In some implementations, the first transistors 470 and the second transistors 570 can be planar transistors and/or semiconductor transistors. In some implementations, the first transistors 470 and the second transistors 570 can form one or more peripheral circuits including any suitable circuits for facilitating the operations of the or more arrays of memory cells by applying and sensing voltage signals and/or current signals through word lines and bit lines to and from each memory cell. The one or more peripheral circuits can include various types of peripheral circuits formed using CMOS technologies.

In some implementations, the first semiconductor structure 520 and the second semiconductor structure 530 can include one or more interconnect layers including interconnect structures to electrically connect the first transistors 470 and the second transistors 570 to the memory cells to transfer electrical signals. In some implementations, a first portion of word line contact 490 can be used to connect a first subset of word lines 524 to the first transistors 470 through the one or more interconnect layers within the first semiconductor structure 520, and a second portion of word line contact 490 can be used to connect a second subset of word lines 524 to the second transistors 570 through the one or more interconnect layers of the first semiconductor structure 520 and the second semiconductor structure 530 and the bonding interface in between. In some implementations, the one or more interconnect layers can include lateral interconnect lines and VIA contacts. In some implementations as shown in FIG. 5, the first semiconductor structure 520 can further include pad contacts 545. In some other implementations not shown, the second semiconductor structure 530 can include pad contacts.

In some implementations, the first semiconductor structure 520 and the second semiconductor structure 530 are bonded together at a bonding interface 535. The bonding interface 535 can be an interface between the first semiconductor structure 520 and the second semiconductor structure 530 formed by any suitable bonding technologies, such as hybrid bonding, anodic bonding, fusion bonding, transfer bonding, adhesive bonding, eutectic bonding, to name a few. The interconnection structures in the first semiconductor structure 520 can be joined with second interconnection structures in the second semiconductor structure 530 at the bonding interface 535 to couple the second transistors 570 with the first transistors 470 and the memory cells through any suitable metal wirings.

As used herein, the term “interconnection structures” and/or “interconnects” can broadly include any suitable types of interconnects, such as middle-end-of-line (MEOL) interconnects and back-end-of-line (BEOL) interconnects. The one or more first and second interconnect layers can further include one or more interlayer dielectric (ILD) layers (also known as “intermetal dielectric (IMD) layers”) in which the interconnect lines and VIA contacts can form. That is, the one or more first and second interconnect layers can include interconnect lines and VIA contacts in multiple ILD layers. The interconnects in the one or more first and second interconnect layers can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

It is understood that 3D memory device 400 can include any other suitable components not shown in FIGS. 4 and 5. It is also understood that the layout and arrangement of different components, such as first transistors 470, transistor contact structures 475, word line contacts 490, dummy channel structures 444, and channel structure 440, may vary in different examples.

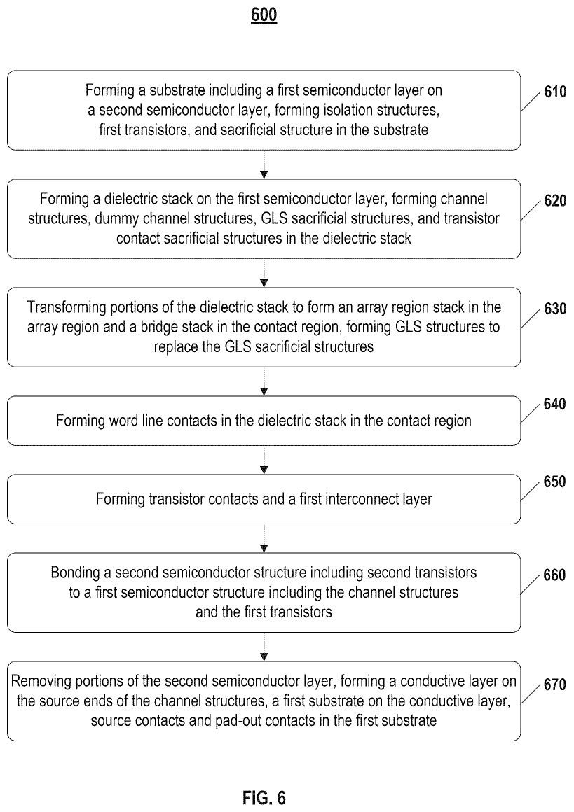

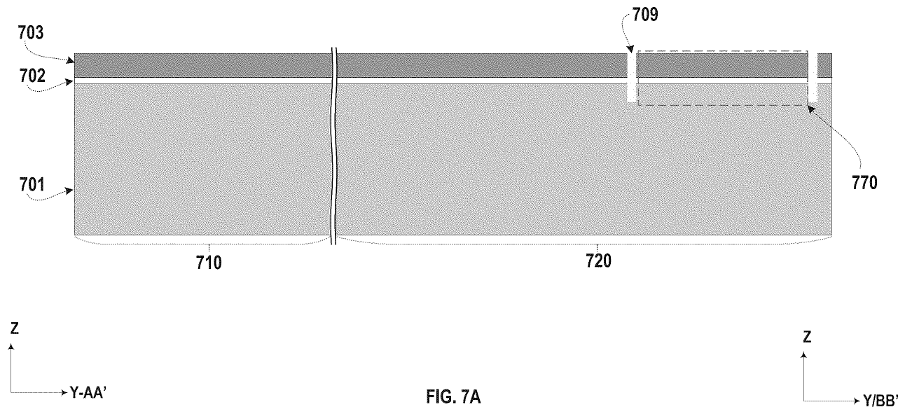

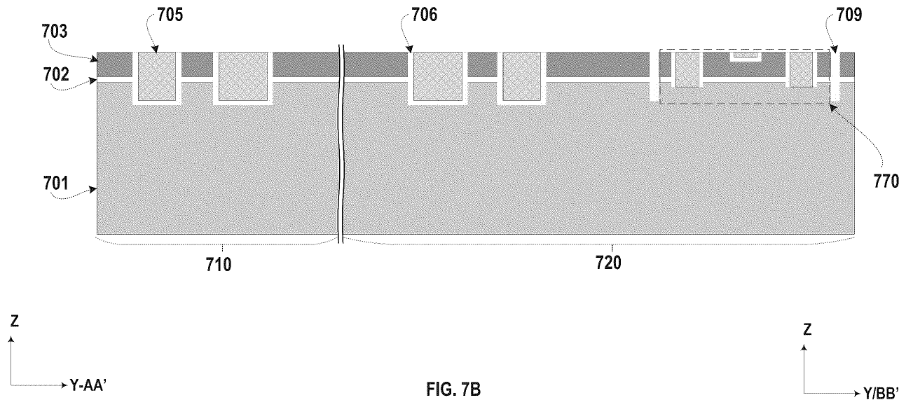

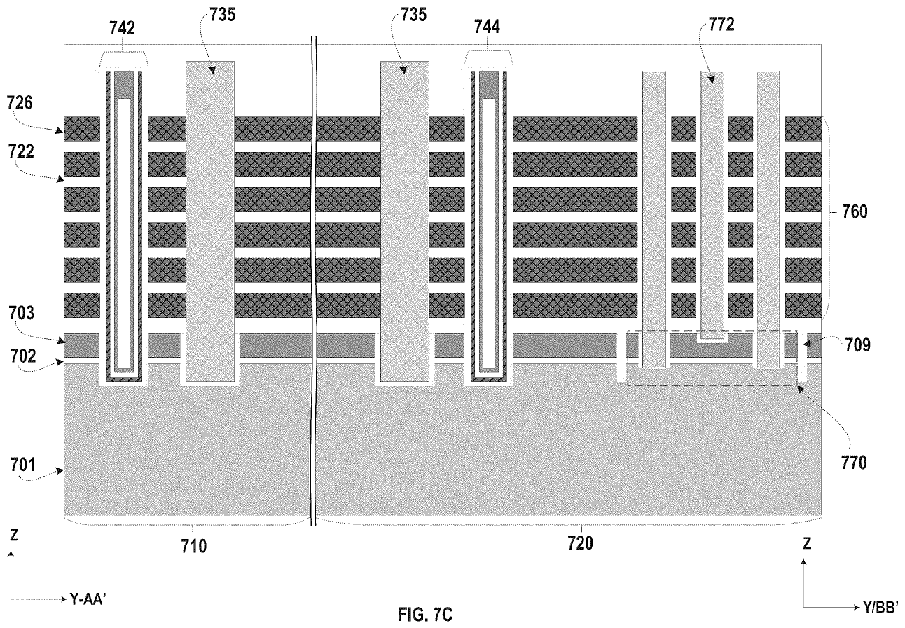

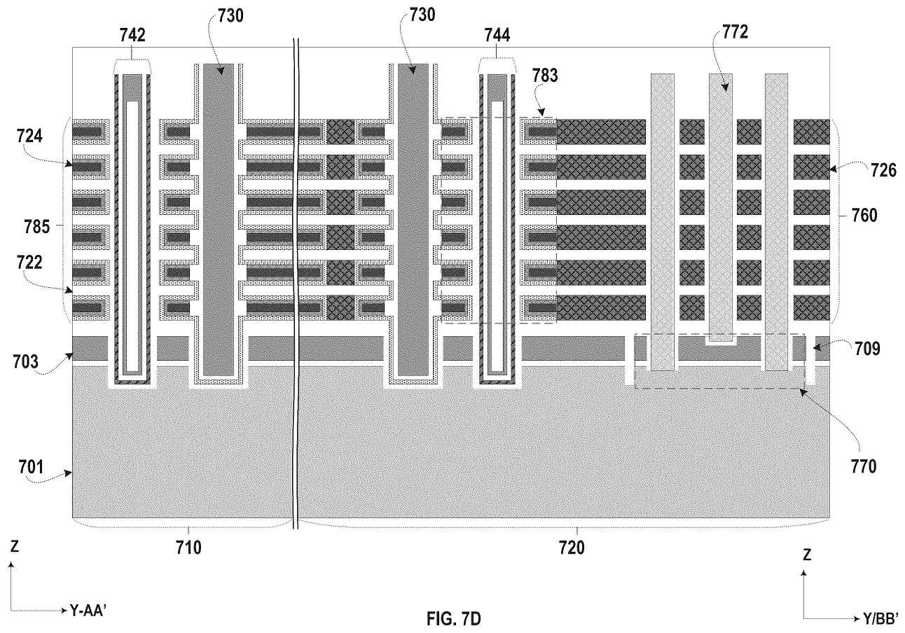

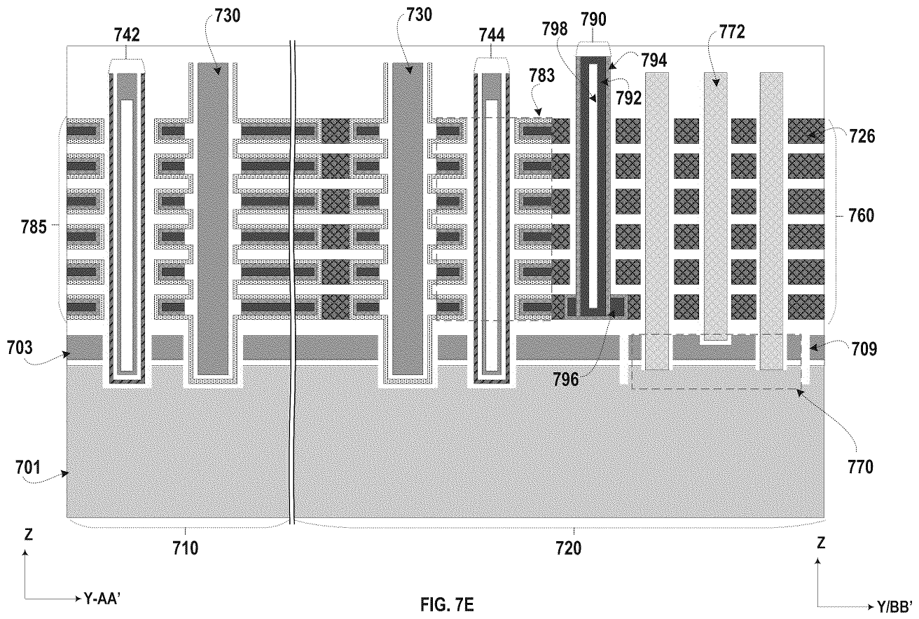

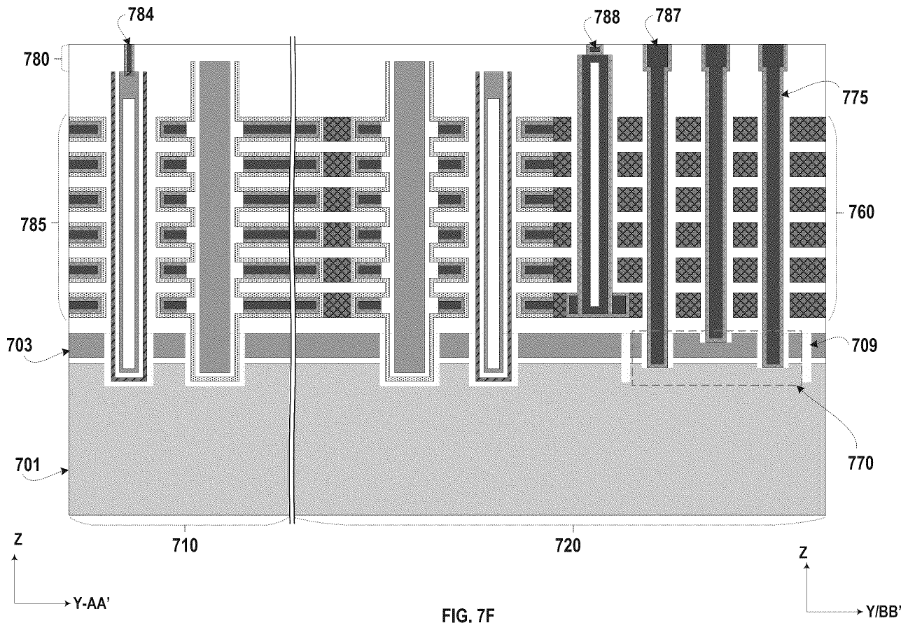

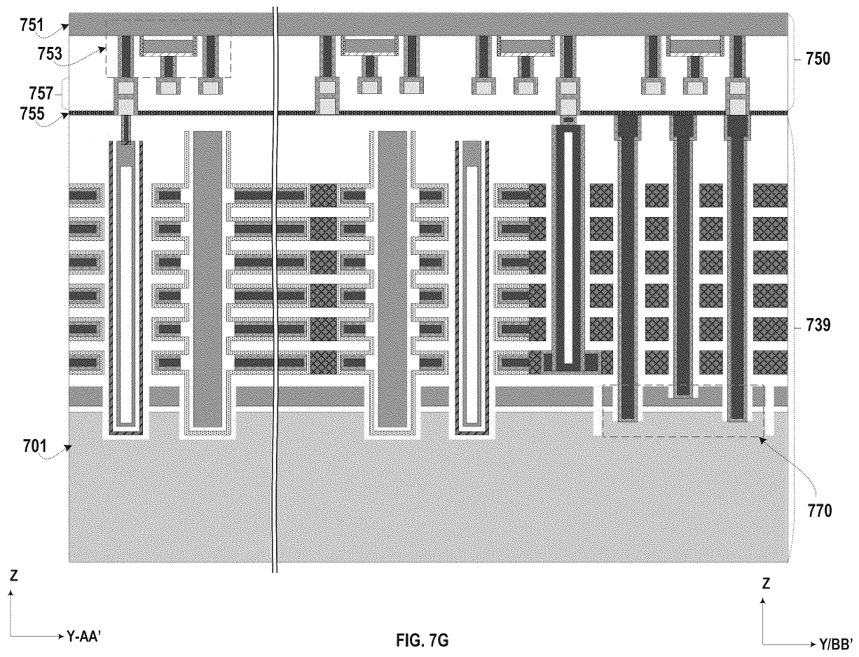

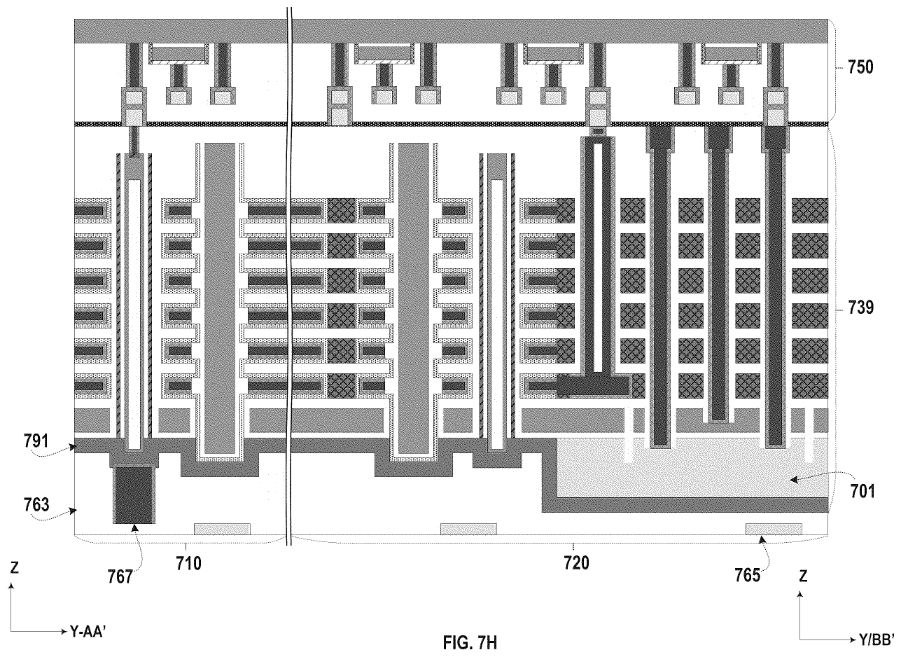

Referring to FIG. 6, a flow diagram of a method 600 for forming a 3D memory device is shown in accordance with some implementations of the present disclosure. FIGS. 7A-7H illustrate schematics of a 3D memory device at certain fabricating stages of the method shown in FIG. 6 in a cross-sectional view according to various implementations of the present disclosure. It is understood that the operations shown in method 600 are not exhaustive and that other operations can be performed as well before, after, or between any of the illustrated operations. Further, some of the operations may be performed simultaneously, or in a different order than shown in FIG. 6.

As shown in FIG. 6, the method can start at operation 610, in which a substrate including a first semiconductor layer on a second semiconductor layer can be formed, isolation structures, first transistors, and sacrificial structure can be formed in the substrate. FIGS. 7A and 7B illustrate cross-sectional views of the 3D structure at different stages of operation 610, according to some implementations of the present disclosure.

As shown in FIG. 7A, a first semiconductor layer 703 can be formed on a dielectric layer 702, which is formed on a second semiconductor layer 701. In some implementations, the first semiconductor layer and the second semiconductor layer can include the same or different semiconductor materials, such as Si (e.g., monocrystalline silicon, polycrystalline silicon), SiGe, GaAs, Ge, etc. The dielectric layer 702 can include any suitable dielectric material, such as oxide silicon, etc. In some implementations, the first semiconductor layer and the second semiconductor layer can be formed by one or more thin film deposition processes including, but not limited to, Chemical Vapor Deposition (CVD), Physical Vapor Deposition (PVD), Atomic Layer Deposition (ALD), or any combination thereof.

In some implementations, isolation structures 709 can be formed in a contact region 720 to extend through the first semiconductor layer 703 and the dielectric layer 702, and extend into the second semiconductor layer 701. In some implementations, each isolation structure 709 can be an enclosed structure in the lateral plane surrounding a region for forming a first transistor in a subsequent operation. In some implementations, forming the isolation structures 709 can include any suitable patterning process. For example, a mask layer (not shown) can be formed over the first semiconductor layer 703. The mask layer can be patterned by using, e.g., photolithography, to form openings corresponding to the isolation structures 709 in the patterned mask layer. A suitable etching process, e.g., dry etch and/or wet etch, can be performed to remove portions of the first semiconductor layer, the dielectric layer 702 and the second semiconductor layer 701 exposed by the openings. A dielectric material can be deposited to fill the openings to form the isolation structures 709. The mask layer can be removed after the formation of the isolation structures 709.

In some implementations, first transistors 770 can be formed in the substrate in the contact region 720. Each first transistor 770 can be formed in the first semiconductor layer 703, the dielectric layer 702, and the second semiconductor layer 701, which are surrounded by a corresponding isolation structure 709. In some implementations, a portion of the first semiconductor layer 703 surrounded by the isolation structure 709 can function as a gate electrode of the formed first transistor 770, and a portion of the dielectric layer 702 surrounded by the isolation structure 709 can function as the gate dielectric layer of the formed first transistor 770. In some implementations, a portion of the second semiconductor layer 701 surrounded by the isolation structure 709 can function as the channel layer of the formed first transistor 770. In some implementations, portions of the second semiconductor layer 701 surrounded by the isolation structure 709 can be doped to function as the source and drain regions of the formed first transistor 770.

As shown in FIG. 7B, isolation structures 709 can be formed in a contact region 720 to extend through the first semiconductor layer 703 and the dielectric layer 702, and extend into the second semiconductor layer 701. In some implementations, each isolation structure 709 can be an enclosed structure in the lateral plane surrounding a region for forming a first transistor in a subsequent operation. In some implementations, forming the isolation structures 709 can include any suitable patterning process. For example, a mask layer (not shown) can be formed over the first semiconductor layer 703. The mask layer can be patterned by using, e.g., photolithography, to form openings corresponding to the isolation structures 709 in the patterned mask layer. A suitable etching process, e.g., dry etch and/or wet etch, can be performed to remove portions of the first semiconductor layer, the dielectric layer 702 and the second semiconductor layer 701 exposed by the openings. A dielectric material can be deposited to fill the openings to form the isolation structures 709. The mask layer can be removed after the formation of the isolation structures 709.

In some implementations, a plurality of sacrificial structures 705 can be formed in both the array region 710 and the contact region 720. In some implementations, the sacrificial structures 705 can extend through the first semiconductor layer 703 and the dielectric layer 702, and extend into the second semiconductor layer 701. In some implementations, the sacrificial structures 705 can be separated from the first semiconductor layer 703, the dielectric layer 702, and the second semiconductor layer 701 by an insulating layer 706. In some implementations, the sacrificial structures 705 in the array region 710 can be used for forming channel structures of 3D NAND memory strings and GLS structures in a subsequent operation, and the sacrificial structures 705 in the contact region 720 can be used for forming dummy channel structures, GLS structures, and transistor contacts in a subsequent operation. In some implementations, forming the sacrificial structures 705 can include any suitable patterning process. For example, a mask layer (not shown) can be formed over the first semiconductor layer 703. The mask layer can be patterned by using, e.g., photolithography, to form openings corresponding to the sacrificial structures 705 in the patterned mask layer. A suitable etching process, e.g., dry etch and/or wet etch, can be performed to remove portions of the first semiconductor layer, the dielectric layer 702 and the second semiconductor layer 701 exposed by the openings. An insulating material can be deposited to cover the sidewalls and bottom surfaces of the openings to form the insulating material, and a sacrificial material can be deposited to fill the openings to form the sacrificial structures 705. The mask layer can be removed after the formation of the sacrificial structures 705.

Referring back to FIG. 6, the method can proceed to operation 620, in which a dielectric stack can be formed on the first semiconductor layer, channel structures, dummy channel structures, gate line slit (GLS) sacrificial structures, and transistor contact sacrificial structures can be formed in the dielectric stack. FIG. 7C illustrates a cross-sectional view of the 3D structure after operation 620, according to some implementations of the present disclosure.

As shown in FIG. 7C, a dielectric stack 760 including interleaved first dielectric layers 722 and second dielectric layers 726 can be formed on the first semiconductor layer 703. A material of the first dielectric layers 722 (e.g., silicon oxide) is different from a material of the second dielectric layers 726 (e.g., silicon nitride). The plurality of first dielectric layers 722 and second dielectric layers 726 are extended in a lateral direction that is parallel to the surface of the first semiconductor layer 703. In some implementations, there are more layers than the lower dielectric layer pairs made of different materials and with different thicknesses in the dielectric stack 760. The dielectric stack 760 can be formed by multiple thin film deposition processes including, but not limited to, CVD, PVD, ALD, or any combination thereof. The dielectric stack 760 can include any suitable number of layers of first dielectric layers 722 and second dielectric layers 726. In some implementations, the total number of layers of the first dielectric layers 722 and second dielectric layers 726 in the dielectric stack 760 is equal to or larger than 64.

As shown in FIG. 7C, operation 620 comprises forming GLS sacrificial structures 735 and transistor contact sacrificial structures 772 in the dielectric stack. In some implementations, GLS sacrificial structures 735 can be formed to extend laterally in a straight line along the word line direction (i.e., X-direction) between two arrays of channel structures 742 in the array region 710 and between two rows of dummy channel structures 744 in the contact region 720 and extend vertically through the dielectric stack 760, the first semiconductor layer 703, and the dielectric layer 702, and extend into the second semiconductor layer 701. In some implementations, the transistor contact sacrificial structures 772 can be formed in the contact region 720 to extend vertically through the dielectric stack 760. Some transistor contact sacrificial structures 772 used for forming gate contacts in the subsequent operations can stop at the first semiconductor layer 703, and some other transistor contact sacrificial structures 772 used for forming source/drain contacts in the subsequent operations can penetrate the first semiconductor layer 703 and the dielectric layer 702, and stop at the second semiconductor layer 701.

The multiple GLS sacrificial structures 735 and the transistor contact sacrificial structures 772 can be formed by forming a mask layer over the dielectric stack 760 and patterning the mask using, e.g., photolithography, to form openings corresponding to the multiple GLS sacrificial structures 735 and the transistor contact sacrificial structures 772 in the patterned mask layer. One or more suitable etching processes, e.g., dry etch and/or wet etch, can be performed to remove portions of the dielectric stack 760 and the sacrificial structures 705 exposed by the openings. A sacrificial material can be deposited to fill the openings to form the GLS sacrificial structures 735, and the transistor contact sacrificial structures 772. The mask layer can be removed after the formation of the GLS sacrificial structures 735 and the transistor contacts sacrificial structures 772.

As shown in FIG. 7C, operation 620 further comprises forming a plurality of channel structures 742 and dummy channel structures 744 in the dielectric stack 760. Each channel structure 742 and dummy channel structure 744 can vertically extend through the dielectric stack 760, the first semiconductor layer 703, and the dielectric layer 702, and extend into the second semiconductor layer 701. In some implementations, the plurality of channel structures 742 can form an array form in the array region 710. In some implementations, the array of channel structures 742 can include a plurality of rows of channel structures 742. Each row of channel structures 742 can be aligned along the word line direction (X-direction). Adjacent rows of channel structures 742 can be misaligned. In some implementations, the array of channel structures 742 can include a plurality of columns of channel structures 742. Each column of channel structures 742 can be aligned along the bit line direction (Y-direction). Adjacent columns of channel structures 742 can be misaligned. In some implementations, the dummy channel structures 744 can be formed in the contact region 720.

In some implementations, the fabricating process for forming the multiple channel structures 742 and dummy channel structure 744 can include forming multiple channel holes (not shown) penetrating the dielectric stack 760 and exposing sacrificial structures 705. The process of forming the multiple channel holes can include forming a hard mask layer (not shown) on the dielectric stack 760, and coating a photoresist layer (not shown) on the hard mask layer. A pattering process can be performed to pattern the hard mask layer. Using the hard mask layer as a mask, an etching process can be followed to etch the dielectric stack 760 to form the multiple channel holes. Each channel hole can completely penetrate the dielectric stack 760 to expose the sacrificial structures 705. The exposed sacrificial structures 705 can be removed by any suitable etching process to extend the channel holes, such that the channel holes completely penetrate the dielectric stack 760, the first semiconductor layer 703, and the dielectric layer 702, and extend into the second semiconductor layer 701. The etching processes to form the multiple channel holes can be dry etching, wet etching, or a combination thereof. After the etching processes, the photoresist layer and the hard mask layer can be removed.

In some implementations, a cleaning process can be performed to clean the multiple channel holes. The cleaning process can be a plasma ashing process including a high-temperature ashing, and/or a wet stripping. For example, a plasma source can be used to generate a reactive species, such as oxygen or fluorine. The reactive species can combine with the photoresist remaining in the channel holes to form ash, which can be removed with a vacuum pump. Specifically, in some implementations, monatomic oxygen plasma can be created by exposing oxygen gas at low pressure to high-power radio waves, which ionize the oxygen gas. The residue of the reaction between the oxygen and photoresist material can generate ash in the plasma asher. The byproducts of the ashing process, such as volatile carbon oxides and water vapor, can be pumped away with the vacuum pump within the plasma asher.

A channel structure 742 and/or a dummy channel structure 744 can be formed in each channel hole in a subsequent process. The multiple channel structures 742 can be arranged in a staggered array form in the array region 710, and the dummy channel structures 744 can be arranged in any suitable manner in the contact region 720. In some implementations, each channel structure 742 can include an optional high-K dielectric layer (not shown), a functional layer on the sidewall of the channel hole or covering the high-K dielectric layer, a channel layer covering the functional layer, and a filling structure enclosed by the channel layer. In some implementations, the functional layer can include a barrier layer, a storage layer, and a tunneling layer. In some implementations, the dummy channel structure 744 can have the same structure as the channel structure 742.

In some implementations, fabrication processes to form the channel structures 742 and/or dummy channel structure 744 can include forming an epitaxial layer (not shown) at the bottom of each channel hole. In some implementations, the epitaxial layer can be a polycrystalline silicon (polysilicon) layer formed by using a selective epitaxial growth (SEG) process. For example, an SEG pre-clean process can be performed to clean the multiple channel holes. A following deposition process can be performed to form a polysilicon layer at the bottom of each channel hole. In some implementations, any suitable doping process, such as an ion metal plasma (IMP) process, can be performed on the polysilicon layer to form the epitaxial layer. In some implementations, the epitaxial layer may not be directly formed on the second semiconductor layer 701. One or more layers can be formed between the epitaxial layer and the second semiconductor layer 701. That is, the epitaxial layer overlays the second semiconductor layer 701.

In some implementations, fabrication processes to form the channel structures 742 and/or dummy channel structure 744 can include forming a high-K dielectric layer (not shown) on the sidewall of each channel hole, and forming a functional layer to cover the high-K dielectric layer. The functional layer can be a composite dielectric layer, such as a combination of a barrier layer, a storage layer, and a tunneling layer. The high-K dielectric layer, the functional layer, including the barrier layer, the storage layer, and the tunneling layer, can be formed by one or more thin film deposition processes, such as ALD, CVD, PVD, any other suitable processes, or any combination thereof.

In some implementations, the barrier layer and/or the high-K dielectric layer can be formed between the storage layer and the sidewall of the channel hole. The barrier layer and/or the high-K dielectric layer can be used to block the outflow of the electronic charges. In some implementations, the barrier layer can be a silicon oxide layer or a combination of silicon oxide/silicon nitride/silicon oxide (ONO) layers. In some implementations, the high-K dielectric layer includes any suitable high dielectric constant (high k-value) dielectrics (e.g., aluminum oxide). In some implementations, the thickness of the barrier layer and/or the high-K dielectric layer can be in a range from about 3 nm to about 20 nm.

The storage layer can be formed between the tunneling layer and the barrier layer. Electrons or holes from the channel layer can tunnel to the storage layer through the tunneling layer. The storage layer can be used for storing electronic charges (electrons or holes) for memory operation. The storage or removal of charge in the storage layer can impact the on/off state and/or conductance of the semiconductor channel. The storage layer can include one or more films of materials including, but are not limited to, silicon nitride, silicon oxynitride, a combination of silicon oxide and silicon nitride, or any combination thereof. In some implementations, the storage layer can include a nitride layer formed by using one or more deposition processes. In some implementations, the thickness of the storage layer can be in a range from about 3 nm to about 20 nm.

The tunneling layer can be formed on the sidewall of the storage layer. The tunneling layer can be used for tunneling electronic charges (electrons or holes). The tunneling layer can include dielectric materials including, but not limited to, silicon oxide, silicon nitride, silicon oxynitride, or any combination thereof. In some implementations, the tunneling layer can be an oxide layer formed by using a deposition process. In some implementations, the thickness of the tunneling layer can be in a range from about 3 nm to about 20 nm.

In some implementations, fabrication processes to form the channel structures 742 and/or dummy channel structure 744 further include forming a channel layer covering the sidewall of the functional layer. In some implementations, the channel layer can be an amorphous silicon layer or a polysilicon layer formed by using a thin film deposition process, such as ALD, CVD, PVD, or any other suitable process. In some implementations, the thickness of the channel layer can be in a range from about 5 nm to 20 nm.

In some implementations, fabrication processes to form the channel structures 742 and/or dummy channel structure 744 further include forming a filling structure to cover the channel layer and fill the channel hole. In some implementations, the filling structure can be an oxide layer formed by using any suitable deposition process, such as ALD, CVD, PVD, etc. In some implementations, the filling structure can include one or more airgaps (not shown).

Referring back to FIG. 6, the method can proceed to operation 630, in which portions of the dielectric stack can be transformed to form an array region stack in the array region and a bridge stack in the contact region, GLS structures can be formed to replace the GLS sacrificial structures. FIG. 7D illustrates a cross-sectional view of the 3D structure after operation 620, according to some implementations of the present disclosure.

In some implementations, the GLS sacrificial structures 735 can be removed to form GLSs. A gate replacement process (also known as the “word line replacement” process) can be performed to replace the second dielectric layers 726 of the dielectric stack 760 with conductive layers 724. In some implementations, after forming the multiple GLSs, the second dielectric layers 726 of the dielectric stack 760 exposed by the GLSs can be removed through the GLSs to form multiple lateral trenches. The multiple lateral trenches can extend in a lateral direction, and can be used as spaces for conductive layers to be formed in a subsequent process.

The second dielectric layers 726 in the array region 710 and portions of the second dielectric layers 726 in the contact region 720 are used as sacrificial layers, and are removed by using any suitable etching process, e.g., an isotropic dry etch or a wet etch. The etching process can have sufficiently high etching selectivity of the material of the second dielectric layers 726 over the materials of the first dielectric layer 722, such that the etching process can have minimal impact on the first dielectric layer 722. The isotropic dry etch and/or the wet etch and a following cleaning process can remove the second dielectric layers 726 in the array region 710 and portions of the second dielectric layers 726 in the contact region 720 in various directions to expose the top and bottom surfaces of each first dielectric layer 722. As such, multiple lateral trenches can then be formed between adjacent first dielectric layers 722. In some implementations, the etchant can include phosphoric acid for etching the second dielectric layers 726 including silicon nitride. The etching rate and/or etching time for the wet etching process can be controlled to control the amount of removal of the second dielectric layer 726 in the contact region 720.

As shown in FIG. 7D, multiple conductive layers 724 can be formed in the multiple lateral trenches. The multiple conductive layers 724 can be used as word lines (i.e., gate electrodes) in the 3D memory device. In some implementations, each conductive layer 724 can be coated with one or more insulating layers used as gate dielectric layers for insulating the respective word line (i.e., gate electrode). In some implementations, the one or more insulating layers can be formed in each of the multiple lateral trenches to cover the exposed surfaces of the lateral trenches with one or more suitable insulating materials. For example, one or more suitable deposition processes, such as CVD, PVD, and/or ALD, can be utilized to deposit the one or more insulating materials into the lateral trenches. In some implementations, a recess etch and/or a chemical-mechanical planarization (CMP) can be used to remove excessive insulating material(s). The one or more insulating materials can include any suitable materials (e.g., high k-value dielectrics) that provide an electric insulating function. For example, the one or more insulating materials can include silicon oxide, silicon nitride, silicon oxynitride, aluminum oxide, titanium nitride, etc., and/or any suitable combinations thereof. In some implementations, multiple insulating layers can have different insulating materials.

The conductive layers 724 can be formed in each lateral trench between the one or more insulating layers. The conductive layers 724 can be formed by filling the lateral trenches with a suitable conductive material, e.g., tungsten, aluminum, copper, cobalt, or any combination thereof, for forming the word lines (i.e., gate electrodes). The conductive material can be deposited into lateral trenches using a suitable deposition method such as CVD, PVD, plasma-enhanced CVD (PECVD), sputtering, metal-organic chemical vapor deposition (MOCVD), and/or ALD. In some implementations, the conductive layers 724 include tungsten formed by CVD. As such, the dielectric stack 760 in the array region 710 is transformed into an array region stack 785, and portions of the dielectric stack 760 adjacent to the GLSs in the contact region 720 are transformed into a bridge stack 783. Both the array region stack 785 and the bridge stack 783 include alternating conductive/dielectric layer pairs.

After the gate replacement process, GLS structures 730 can be formed in each GLS. In some implementations, the GLS structure 730 is an insulating structure that does not include any interconnects therein (i.e., not functioning as the source contact). It can be formed by depositing one or more dielectric materials to fill the GLS. In some other implementations, the GLS structure 730 is a source contact further including a conductive portion (e.g., including W, polysilicon, and/or TiN) circumscribed by a slit spacer layer, the fabricating process for forming the GLS structure 730 can include forming a slit spacer layer on the sidewalls of the multiple GLSs. The slit spacer layer is also referred to as a gate line spacer (GLSP) layer, and can be used to provide electrical insulation between the conductive layers 724 and the conductive portion formed in a subsequent process.

In some implementations, the fabricating process for forming the slit spacer layer can include a word line gate recess process. Portions of the conductive layers 724 (word lines) exposed by the GLSs can be removed by a recess etching process. In some implementations, in order to ensure the insulation between the conductive layers 724 (word lines), a recess etching process, such as a wet etching process, can be performed to remove portions of the conductive layers 724 exposed by the GLSs. In doing so, a recess can be formed in each lateral trench adjacent to the GLSs.

In some implementations, the fabricating process for forming the GLS structure 730 can include forming a conductive portion in each GLS. The conductive portion can be in contact with a doped region (not shown) in the second semiconductor layer 701, and is used as an array common source (ACS) of the multiple NAND strings. In some implementations, the conductive portion can be formed by depositing a conductive material, such as polysilicon, silicides, tungsten, aluminum, copper, and/or combinations thereof, etc. The conductive material can be deposited into the multiple GLSs using a suitable deposition method such as CVD, PVD, ECVD, sputtering, MOCVD, and/or ALD. In some implementations, the fabricating process for forming the GLS structure 730 can include forming a dielectric portion in each GLS. In some implementations, the dielectric portion can be formed by depositing a dielectric material into the multiple GLSs using a suitable deposition method such as CVD, PVD, ECVD, sputtering, MOCVD, and/or ALD.

Referring back to FIG. 6, the method proceeds to operation 640, in which word line contacts can be formed in the dielectric stack in the contact region. FIG. 7E illustrates a cross-sectional view of the 3D structure after operation 640, according to some implementations of the present disclosure.

As shown in FIG. 7E, word line contacts 790 can be formed in the dielectric stack 760 in the contact region 720 and in contact with the conductive layers 724 in the bridge stack 783. In some implementations, the word line contacts 790 can be formed to extend vertically in the contact region 720 of the dielectric stack 760. In some implementations, different word line contacts 790 can be formed to have different depths in the Z-direction. In some implementations, each word line contact 790 can be formed to include a vertical conductive structure 792, and a lateral conductive structure 796 below and in contact with the vertical conductive structure 792. The vertical conductive structure 792 and the lateral conductive structure 796 can include conductive materials including, but not limited to, W, Co, Cu, Al, TiN, polysilicon, doped silicon, silicides, or any combination thereof.

In some implementations, each word line contact 790 can be formed to further include a spacer layer 794 circumscribing the vertical conductive structure 792. The spacer layer 794 can include dielectric materials including, but not limited to, silicon oxide, silicon nitride, silicon oxynitride, or any combination thereof. In some implementations, each word line contact 790 can be formed to further include a filling layer 798 surrounded by the vertical conductive structure 792 and the lateral conductive structure 796. The filling layer 798 can include dielectric materials, including, but not limited to, silicon oxide, silicon nitride, silicon oxynitride, or any combination thereof. In some implementations, the vertical conductive structure 792 and the lateral conductive structure 796 include TiN/W, and the spacer layer and the filling layer include silicon oxide.

In some implementations, forming the plurality of word line contacts 790 can include the following steps. First, multiple openings each extending into a part of the dielectric stack 760 including the interleaved first dielectric layers 722 and the second dielectric layers 726 are formed at different depths to expose respective ones of second dielectric layers 726. In some implementations, the multiple openings extend vertically through different numbers of pairs of first and second dielectric layers 722 and 726 of the dielectric stack 760 in the contact region 720, stopping at different depths to expose different second dielectric layers 726.

The multiple openings can be formed using a chopping process. As used herein, a “chopping” process is a process that increases the depth of one or more openings extending through the dielectric stack 760 by a plurality of etching cycles. Each etch cycle can include one or more dry etch and/or wet etch processes that etch one pair of first and second dielectric layers 722 and 726, i.e., reducing the depth by one dielectric layer pair. The purpose of the chopping process is to make the openings at different depths. Accordingly, depending on the number of openings, a certain number of chopping processes, along with a number of chopping masks, may be needed. It is understood that the number of chopping masks, the sequence of the chopping masks, the design (e.g., the number and pattern of openings) of each chopping mask, and/or the reduced depth by each chopping process (e.g., the number of etching cycles) may affect the specific depth of each opening after the chopping process.

In some implementations, the spacer layer 794 is formed on the sidewalls and a bottom of each of the openings, thereby covering first dielectric layers 722 and second dielectric layers 726 exposed from the sidewalls of the openings. In some implementations, the spacer layer 794 is formed by depositing dielectric materials, such as silicon oxide, using one or more thin film deposition processes, such as ALD, CVD, PVD, any other suitable processes, or any combination thereof, over the sidewalls and the bottom surfaces of the openings. In some implementations, the spacer layer 794 on the bottom of each of the openings is removed, for example, by dry etching, to expose the respective part of the second dielectric layer 726. In some implementations, the etching rate, direction, and/or duration of Reactive Ion Etching (RIE) are controlled to etch only the part of the spacer layer 794 on the bottom surface, but not on the sidewalls, of the openings, i.e., “punching” through the spacer layer in the Z-direction to expose only a corresponding second dielectric layer 726 from the bottom, but not other second dielectric layers 726 from the sidewalls.

To form the word line contacts 790, parts of the second dielectric layers 726 in the contact region 720 of the dielectric stack 760 can be replaced with the lateral conductive structure 796, respectively, through the openings. For example, at least a part of a corresponding exposed second dielectric layer 726 can be removed through each opening by wet etching to form a lateral recess. In some implementations, the etchant can include phosphoric acid for etching the second dielectric layer 726 including silicon nitride. The etching rate and/or etching time for the wet etching process can be controlled to control the amount of the removal of the second dielectric layer 726, thereby controlling the lateral size of the formed lateral recess. The lateral conductive structure 796 can be formed in the lateral recess by depositing a conductive material through the opening. The conductive material, such as a metal material, can be deposited using one or more thin film deposition processes, such as ALD, CVD, PVD, any other suitable processes, or any combination thereof, to fill the lateral recess to form the lateral conductive structure 796.

In some implementations, vertical conductive structures 792 are formed in the openings in contact with the lateral conductive structures 796, respectively. In some implementations, the vertical conductive structures 792 can be formed in the same process as forming the lateral conductive structures 796 by depositing the conductive material not only into the lateral recesses, but also on the sidewalls and the bottom surface of openings, using one or more thin film deposition processes, such as ALD, CVD, PVD, any other suitable processes, or any combination thereof. In some implementations, a filling layer 798 can be formed in the vertical conductive structures 792 by depositing a dielectric material.

Referring back to FIG. 6, the method proceeds to operation 650, in which transistor contacts and a first interconnect layer can be formed. FIG. 7F illustrates a cross-sectional view of the 3D structure after operation 650, according to some implementations of the present disclosure.

As shown in FIG. 7F, transistor contacts 775 can be formed each extending vertically in the dielectric stack 760 in the contact region. The transistor contacts 775 can be formed extending vertically in the dielectric stack 760 landing on the first semiconductor layer 703 or the second semiconductor layer 701. In some implementations, fabricating processes of forming the transistor contacts 775 can include performing a suitable etching process, e.g., dry etch and/or wet etch, to remove the transistor contact sacrificial structures 772 to form contact holes. In some implementations, the contact holes can expose the gate electrode and the source/drain regions of each first transistors 770. A mask layer (not shown) can be used to control the locations and sizes of the contact holes during the etching process. In some implementations, a deposition process can then be performed to fill the contact holes with any suitable conductive material (e.g., W, Co, Cu, Al, TiN, polysilicon, doped silicon, silicides, etc.) to form the transistor contacts 775. It is noted that, before depositing the conductive material, an optional spacer layer can be formed by depositing a dielectric material (e.g., silicon oxide, silicon nitride, silicon oxynitride, etc.) on sidewalls of the contact holes. A CMP process can be performed to make the top surfaces of the transistor contacts 775 flush with one another.

As shown in FIG. 7F, a first interconnect layer 780 including a plurality of first interconnects can be formed on the formed 3D structure. In some implementations, the first interconnect layer 780 can include one or more ILD layers in which the first interconnects are embedded. In some implementations, the first interconnects in the first interconnect layer 780 can include channel structure interconnects 784, word line interconnects 788, and transistor interconnects 787. In some implementations, the first interconnects can include lateral interconnect lines, VIA contacts, and/or any other suitable types of interconnects, formed by MEOL or BEOL processes. The channel structure interconnects 784, word line interconnects 788, and transistor interconnects 787 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

Referring back to FIG. 6, the method proceeds to operation 660, in which a second semiconductor structure including second transistors can be bonded to a first semiconductor structure including the channel structures and the first transistors. FIG. 7G illustrates a cross-sectional view of the 3D structure after operation 660, according to some implementations of the present disclosure.

A second semiconductor structure 750 including a plurality of second transistors 753 is formed in operation 660. In some implementations, forming the second semiconductor structure 750 can include forming the second transistors 753 on a second substrate 751. The second substrate 751 can be any suitable semiconductor substrate having any suitable structure, such as a monocrystalline single-layer substrate, a polycrystalline silicon (polysilicon) single-layer substrate, a polysilicon and metal multi-layer substrate, etc. In some implementations, the second transistors 753 can be formed on second substrate 751 using a plurality of processes including, but not limited to, photolithography, etching, thin film deposition, thermal growth, implantation, chemical mechanical polishing (CMP), and any other suitable processes.

In some implementations, trench isolations (e.g., STIs, not shown) can be formed in the second substrate 751 to separate the second transistors 753 from each other. In some implementations, doped regions (e.g., wells, sources, and drains of second transistors 753, not shown) can be formed on or in second substrate 751 by ion implantation and/or thermal diffusion, which function, for example, as source regions and/or drain regions of second transistors 753. In some implementations, a first thickness of gate dielectric of the first transistors 770 is greater than a second thickness of gate dielectric of the second transistors 753, such that the operating voltages of the formed second transistors 751 are lower than the operating voltages of the first transistors 770. In some implementations, the second transistors 753 can be formed using any suitable CMOS technologies.

As shown in FIG. 7G, a second interconnect layer 757 including a plurality of second interconnects can be formed on the second transistors 753. In some implementations, the second interconnect layer 757 can include one or more ILD layers in which the second interconnects are embedded. In some implementations, the second interconnects in the second interconnect layer 757 can be coupled to the gates and source/drain regions of the second transistors 753. In some implementations, the second interconnects can include lateral interconnect lines, VIA contacts, and/or any other suitable types of interconnects, formed by MEOL or BEOL processes. The second interconnects can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

In some implementations, the second semiconductor structure 750 including the second transistors 753 can be bonded to the first semiconductor structure 739 including the channel structures 742 and the first transistors 770 in a face-to-face manner. The bonding interface 755 can be an interface between the first semiconductor structure 739 and the second semiconductor structure 750 formed by any suitable bonding technologies, such as hybrid bonding, anodic bonding, fusion bonding, transfer bonding, adhesive bonding, eutectic bonding, to name a few. As illustrated in FIG. 7G, the second substrate 751 and components formed thereon (e.g., second transistors and the second interconnect layer 757) are flipped upside down. As such, the first semiconductor structure 739 and the second semiconductor structure 750 can be bonded together in a face-to-face manner at bonding interface 755, according to some implementations. In some implementations, a treatment process, e.g., a plasma treatment, a wet treatment, and/or a thermal treatment, is applied to the bonding surfaces of the first semiconductor structure 739 and the second semiconductor structure 750 prior to the bonding. After the bonding, corresponding first interconnect contacts of the first interconnect layer 780 and the second interconnect contacts in the second interconnect layer 757 are aligned and in contact with one another, such that channel structures 742 and the first transistor 770 can be electrically connected to the second transistors 753.

Referring back to FIG. 6, the method proceeds to operation 670, in which portions of the second semiconductor layer can be removed, a conductive layer can be formed on the source ends of the channel structures, a first substrate can be formed on the conductive layer, source contacts and pad-out contacts can be formed in the first substrate. FIG. 7H illustrates a cross-sectional view of the 3D structure after operation 670, according to some implementations of the present disclosure.

As shown in FIG. 7H, the second semiconductor layer 701 in the array region 710 and portions of the second semiconductor layer 701 under the bridge stack 783 in the array region 710 can be removed by any suitable process. A conductive layer 791 can be formed in contact with the source ends of the channel structures 742 and functions as a common source line of the array of NAND memory strings. A first substrate 763 including any suitable substrate material can be formed on the conductive layer 791. Ssource contacts 767 and/or pad-out contacts 765 can be formed in or on the first substrate 763.

The foregoing description of the specific implementations will so fully reveal the general nature of the present disclosure that others can, by applying knowledge within the skill of the art, readily modify and/or adapt for various applications such specific implementations, without undue experimentation, without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Implementations of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections may set forth one or more but not all implementations of the present disclosure as contemplated by the inventor(s), and thus, are not intended to limit the present disclosure and the appended claims in any way.

The breadth and scope of the present disclosure should not be limited by any of the above-described implementations, but should be defined only in accordance with the following claims and their equivalents.

What is claimed is:

1. A memory device, comprising:
a first semiconductor structure comprising:
an array region comprising:
an array region stack comprising conductive layers and first dielectric layers that are interleaved in a vertical direction, and
an array of channel structures each vertically extending through the array region stack; and
a contact region comprising:
first transistors,
a dielectric stack on the first transistors and comprising the first dielectric layers and second dielectric layers that are interleaved in the vertical direction,
first contact structures extending in the dielectric stack and each being connected with a corresponding one of the conductive layers in the array region stack, and
second contact structures extending through the dielectric stack and in contact with the first transistors.

2. The memory device of claim 1, wherein the contact region comprising further comprises:
a bridge stack on a lateral side of the dielectric stack and comprising the conductive layers and the first dielectric layers that are interleaved in the vertical direction;
wherein each of the first contact structures is connected with the corresponding one of the conductive layers through the bridge stack.

3. The memory device of claim 2, further comprising a first semiconductor layer in the array region and the contact region, wherein:
the array region stack, the dielectric stack, and the bridge stack are located on the first semiconductor layer;
each channel structure extending through the first semiconductor layer in the array region; and
portions of the first semiconductor layer in the contact region comprise gate structures of the first transistors.

4. The memory device of claim 3, further comprising:
a second semiconductor layer in the contact region, on a side of the first semiconductor layer opposite to the dielectric stack, and comprising sources and drains of the first transistors.

5. The memory device of claim 4, further comprising:
isolation structures extending through the first semiconductor layer in the contact region, and laterally surrounding the gate structure of each first transistor.

6. The memory device of claim 4, wherein the second contact structures comprise:
gate contacts extending through the dielectric stack and in contact with the first semiconductor layer; and
source/drain contacts extending through the dielectric stack and the first semiconductor layer, and in contact with the second semiconductor layer.

7. The memory device of claim 2, wherein the first contact structure comprises:
a vertical conductive structure vertically extending in the dielectric stack; and
a lateral conductive structure at a bottom of the vertical conductive structure and laterally in contact with the corresponding one of the conductive layers of the bridge stack.

8. The memory device of claim 7, wherein each first contact structure further comprises:
a spacer layer laterally surrounding the vertical conductive structure to separate the vertical conductive structure from the dielectric stack.

9. The memory device of claim 2, further comprising:
a first slit structure and a second slit structure extending in parallel along a first lateral direction and vertically in the array region stack and the bridge stack, wherein:
the bridge stack comprises a first portion adjacent to the first slit structure and a second portion adjacent to the second slit structure; and
the dielectric stack is located between the first portion and the second portion of the bridge stack along a second lateral direction perpendicular to the first lateral direction.

10. The memory device of claim 1, further comprising:
a second semiconductor structure comprising second transistors;
wherein the first semiconductor structure and the second semiconductor structure are bonded together.

11. A memory device, comprising:
a first semiconductor structure comprising:
an array region comprising:
an array region stack on a first semiconductor layer, and
an array of channel structures each vertically extending through the array region stack; and
a contact region comprising:
first transistors, wherein upper surfaces of gate structures of the first transistors are aligned with an upper surface of the first semiconductor layer,
a dielectric stack on the first transistors, and
second contact structures extending through the dielectric stack and in contact with the first transistors.

12. The memory device of claim 11, wherein:
the first semiconductor layer and the gate structures of the first transistors have a same thickness and a same type of dopant.

13. The memory device of claim 11, wherein:
the array region stack comprises conductive layers and first dielectric layers that are interleaved in a vertical direction; and
the dielectric stack comprises the first dielectric layers and second dielectric layers that are interleaved in the vertical direction.

14. The memory device of claim 13, wherein the contact region further comprises:
a bridge stack comprising the conductive layers and the first dielectric layers that are interleaved in the vertical direction; and
first contact structures extending in the dielectric stack and each being in contact with a corresponding one of the conductive layers.

15. The memory device of claim 12, further comprising:
a second semiconductor layer in the contact region, on a side of the gate structures of the first transistors opposite to the dielectric stack, and comprising sources and drains of the first transistors.

16. The memory device of claim 15, further comprising:
isolation structures extending through the first semiconductor layer in the contact region, and laterally surrounding the gate structure of each first transistor.

17. The memory device of claim 15, wherein the second contact structures comprise:
gate contacts extending through the dielectric stack and in contact with the gate structures of the first transistors; and
source/drain contacts extending through the dielectric stack and the gate structures, and in contact with the second semiconductor layer.

18. The memory device of claim 14, wherein each first contact structure comprises:
a vertical conductive structure vertically extending in the dielectric stack; and
a lateral conductive structure at a bottom of the vertical conductive structure and laterally in contact with the corresponding one of the conductive layers of the bridge stack.

19. The memory device of claim 15, further comprising:
a first slit structure and a second slit structure extending in parallel along a first lateral direction and vertically in the array region stack and the bridge stack, wherein:
the bridge stack comprises a first portion adjacent to the first slit structure and a second portion adjacent to the second slit structure; and
the dielectric stack is located between the first portion and the second portion of the bridge stack along a second lateral direction perpendicular to the first lateral direction.

20. The memory device of claim 11, further comprising:
a second semiconductor structure comprising second transistors;
wherein the first semiconductor structure and the second semiconductor structure are bonded together.
